(19) United States
(12) Patent Application Publication
(10) Pub. No.: US 2007/0210342 A1
(43) Pub. Date: Sep. 13, 2007

(54) Vertical charge transfer active pixel sensor

(75) Inventor: Taner Dosluoglu, New York, NY (US)

Correspondence Address: STEPHEN B. ACKERMAN, 28 DAVIS AVENUE, POUGHKEEPSIE, NY, 12603, US

(73) Assignee: Dialog Imaging Systems GmbH

(21) Appl. No.: 11/789,394

(22) Filed: Apr. 24, 2007

Related U.S. Application Data
(63) Continuation-in-part of application No. 10/706,839, filed on Nov. 12, 2003, now abandoned.
(60) Provisional application No. 60/450,089, filed on Feb. 26, 2003.

(51) Int. Cl. H01L 29/768

(52) U.S. Cl. 257/222; 257/E29.229

(57) ABSTRACT

An active pixel sensor and method of operating an active pixel sensor comprising an N well of n type silicon formed in a p type silicon substrate and a P well of p type silicon is formed in the N well. A deep N well is formed of n type silicon underneath the P well. The edges of the deep N well contact the bottom of the N well forming an overlap region which can either be not depleted of charge carriers thereby electrically connecting the N well to the deep N well or depleted of charge carriers thereby electrically isolating the N well from the deep N well. N regions formed in the P well and P regions formed in the N well are used to reset the pixel and to read the pixel after a charge integration period. An array of P wells formed within N wells can be used to form an array of active pixel sensors. In this array an overlap region is formed between each N well and the deep N well. In an array of active pixel sensors the N regions can be binned together by using the overlap regions to connect each N well to the deep N well thereby achieving noise suppression during the reset cycle.

This Patent Application is a Continuation In Part of application Ser. No. 10/706,839; filed Nov. 12, 2003; which claimed priority to U.S. Provisional Patent Application No. 60/450,089; filed Feb. 2, 2003; herein incorporated by reference.

### BACKGROUND OF THE INVENTION

(1) Field of the Invention

This invention relates to a vertical charge transfer active pixel sensor using a deep N well or P well to achieve vertical charge transfer.

(2) Description of the Related Art

U.S. Pat. No. 6,501,109 to Chi describes an active CMOS pixel sensor with a p well within a deep n well.

U.S. Pat. No. 6,001,667 to Saitoh et al. describes a method of manufacturing a semiconductor detector for detecting light radiation showing a p well within a deep n well.

U.S. Pat. No. 5,600,127 to Kimata describes vertical charge transfer using an n well.

U.S. Pat. No. 5,210,433 to Ohsawa et al. describes a solid state CCD imaging device showing a potential well and a deep potential well for vertical charge transfer.

U.S. Pat. No. 5,040,038 to Yutani et al. describes a solid state image sensor showing a transfer potential well under a transfer electrode.

U.S. Pat. No. 4,875,101 to Endo et al. describes a solid state imaging device showing shallow and deep potential wells for vertical charge transfer.

U.S. Pat. No. 4,906,856 to Iwanami et al. describes a bipolar device used as a photoelectric conversion device comprising a plurality of doped regions electrically isolated from one another. Each doped region comprises a first region containing base, collector, and emitter regions arranged to constitute a bipolar phototransistor.

U.S. Pat. No. 6,023,293 to Watanabe et al. describes an active solid-state imaging device wherein the image sensor portion and the driving circuit portion are formed in separate regions in the identical semiconductor substrate.

### SUMMARY OF THE INVENTION

It is the objective of this invention to provide an Active Pixel Sensor structure which operates using controlled vertical charge transfer.

It is another objective of this invention to provide a method of operating an Active Pixel Sensor structure using controlled vertical charge transfer.

These objectives are achieved using a deep well structure. A silicon substrate having an epitaxial layer of p type silicon is provided. An N well of n type silicon is formed wherein the N well surrounds an island of p type silicon. A deep N well is formed of n type silicon underneath the island of p type silicon thereby forming a P well of p type silicon. The P well is within the boundaries of the N well and above the deep N well. The edges of the deep N well contact the bottom of the N well forming a lightly doped overlap region which can either electrically connect the N well to the deep N well or electrically isolate the N well from the deep N well by either depleting or not depleting the overlap region of charge carriers. N regions formed in the P well and P regions formed in the N well are used to reset the pixel and to read the pixel after a charge integration period. The overlap region can be used to connect the N well to the deep N well so that carriers generated in the deep N well can be transferred to the N well. The overlap region can also be depleted to isolate the N well from the deep N well so that charges transferred from the deep N well to the N well can be stored in the N well.

Alternatively, a silicon substrate having an epitaxial layer of n type silicon is provided. A P well of p type silicon is formed wherein the P well surrounds an island of n type silicon. A deep P well is formed of p type silicon underneath the island of n type silicon thereby forming an N well of n type silicon. The N well is within the boundaries of the P well and above the deep P well. The edges of the deep P well contact the bottom of the P well forming an overlap region which can either electrically connect the P well to the deep P well or electrically isolate the P well from the deep P well. P regions formed in the N well and N regions formed in the P well are used to reset the pixel and to read the pixel after a charge integration period. The overlap region can be used to connect the P well to the deep P well so that carriers generated in the deep P well can be transferred to the P well. The overlap region can be depleted to isolate the P well from the deep P well so that charges transferred from the deep P well to the P well can be stored in the P well.

### BRIEF DESCRIPTION OF THE DRAWINGS

FIG. 1 shows a cross section view of the active pixel sensor of this invention.

FIG. 2 shows a top view of the active pixel sensor of this invention.

FIG. 3 shows a cross section view of two pixels joined by a single deep N well or deep P well.

FIG. 4 shows a top view of a portion of an array of active pixel sensors of this invention.

FIG. 5 shows a cross section view top view of a portion of an array of active pixel sensors of this invention.

### DESCRIPTION OF THE PREFERRED EMBODIMENTS

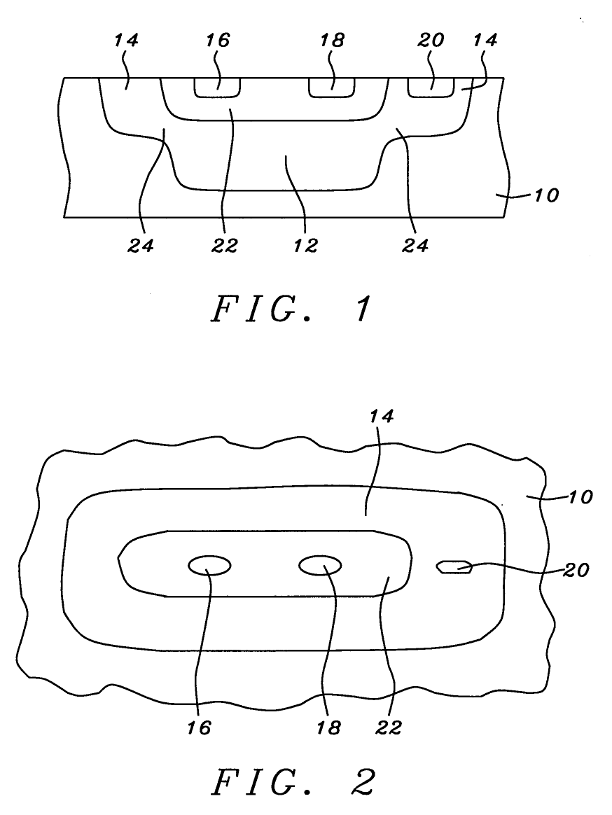

FIG. 1 shows a cross section view and FIG. 2 a top view of the Active Pixel Sensor of this invention. In the first embodiment an N well 14 of n type silicon is formed in a p type epitaxial silicon substrate 10. A P well 22 is formed in the N well, 14 thereby forming a deep N well 12 under the P well 22, so that the N well 14 surrounds the P well 22 and an overlap region 24 between the N well 14 and the deep N well 12. The deep N well 12 is formed a distance of between about 0.3 and 1.0 microns below the surface of the substrate and is located directly below the P well 22. The overlap region 24 connects the N well 14 and the deep N well 12 and is designed such that the overlap region 24 will be depleted of charge carriers or not depleted of charge carriers depending on the potential of the P Well 22. To accomplish the desired characteristics of the N well 14, P well 22, and deep N well 12 the doping levels of these regions is typically less than 1×10¹⁷ impurities per cm³ which is significantly less than the doping level of a bipolar transistor which is typically greater than 1×10¹⁸ impurities per cm³. A first N region 16 and a second N region 18 are formed in the P well 22. A P region 20 is formed in the N well 14. With no bias on the structure the overlap region 24 is not depleted of charge and the deep N well 12 and the N well are connected and are at the same potential.

The alignment tolerance of the process used to form the N well 14, P well 22, and deep N well 12 will determine maximum allowed doping level of the overlap region 24 and the voltage required to deplete the overlap region 24. If the P well is biased at the same potential as the p type substrate 10, typically zero volts, and the width of the overlap region 24 between the N well 14 and the deep N well 12 is controlled to between about 0.3 and 0.7 microns a doping level of less than 1×10¹⁵ impurities per cm³, for the N well 14 and deep N well 12, will be required in order to deplete the overlap region 24 and disconnect the N well 14 from the deep N well 12 with a 3 volt bias between the N well 14 and deep N well 12. If a negative bias is applied to the P well 22 a higher doping level up to about 1×10¹⁶ impurities per cm³ for the N well 14 and deep N well 12 could be used. All of the bias voltages herein described are referenced to the p type epitaxial substrate.

In the operation of the pixel the N well 14 and the P well 22 are set at a positive bias potential, for example 3 volts. This sets the potential of the deep N well 12 at the same potential as the N well 14 and the overlap region 24 is not depleted of charge. In this case even the junction between the P well 22 and deep N well 12 is forward biased. The potential of the P well is then set to a negative bias potential, for example −3 volts, without changing the potential of the N well 14 and the overlap region 24 is depleted of charge disconnecting the N well 14 from the deep N well 12. This isolates the deep N well 12 during a charge integration period and photo generated electrons in the epitaxial layer 10 underneath the deep N well 12 lowering the potential of the deep N well, for example between 3 volts and 0 volts wherein 3 volts in no signal and 0 volts is the saturation level. Since the overlap region 24 is still depleted the N well 14 remains at the positive voltage, in this example 3 volts.

After the charge integration period has been completed the N well 14 can be disconnected from the bias voltage, in this example 3 volts, and the potential of the P well 22 is set to a bias potential of 0 volts. The overlap region 24 is then not depleted, and the charge accumulated by the deep N well 12 is transferred to the N well. The potential of the P well 22 can be adjusted to adjust the amount of depletion of the overlap region 24 and thereby control the charge transfer to the N well 14. In this example the doping levels would be chosen so that the overlap region 24 is depleted when the P well 22 is biased at −3 volts and is not depleted when the P well 22 is at 0 volts.

In one mode of operation the potential of the N well 14 can be read before and after the transfer of the charge from the deep N well 12 to the N well 14 providing a pixel correlated double sampling operation.

The charge transfer from the deep N well 12 to the N well 14 is primarily determined by the P well 12 potential and the N well 14 potential. In another mode of operation the P well 22 could be left floating and the charge transfer would be controlled by adjusting the potential of the N well 14. In this case the P well 22 will be used in a manner similar to a floating gate sense node and the signal can be readout prior to, during, and after the charge transfer from the deep N well 12 to the N well 14.

The previous example showed a single P well 22 formed in a single N well 14 with a deep N well 12. An overlap region 24 provides communication or isolation between the N well 14 and deep N well. A number of N wells with a single deep N well can be used, having a P well formed in each of the N wells, and depletion regions to provide communication or isolation between each of the N wells and the deep N well. FIG. 3 shows a structure having two N wells, a first N well 34 and a second N well 36, having overlap regions connecting both N wells to the same deep N well 32. A P region 48 separates the two N wells. The first N well 34 is connected to the deep N well 32 by a first overlap region 42. The second N well 36 is connected to the deep N well 32 by a second overlap region 44. There is a first P well 38 in the first N well 34 and a second P well 40 is the second N well 36. The overlap regions, 42 and 44, are designed to allow depletion of the first overlap region 42 while the second overlap region 44 is not depleted, depletion of the second overlap region 44 while the first overlap region 42 is not depleted, depletion of both overlap regions, or leaving both overlap regions not depleted. During reset neither the first overlap region 42 nor the second overlap region 44 are depleted and the first N well 34, the second N well 36, and the deep N well 32 are set to the same potential. This will reduce the kTC noise during reset. Binning of the first N well 34 and the second N well 36 can be accomplished by adjusting the potentials so that neither the first overlap region 42 nor the second overlap region 44 are depleted.

In the structures shown in FIGS. 1 and 3, sufficiently high voltage is applied to deplete the overlap regions; 24 in FIG. 1, and 42 and 44 in FIG. 3; during the charge integration period. After the integration period has been completed, charge transfer can be controlled by controlling the amount of depletion in the overlap regions; 24 in FIG. 1, and 42 and 44 in FIG. 3. In the structure shown in FIG. 3, the overlap regions, 42 and 44, can be turned on (not depleted) during the reset operation to connect the N well regions, 36 and 38, to achieve reset noise suppression and turned off (depleted) after reset to isolate the N well regions, 36 and 38. In the structure shown in FIG. 3, the overlap regions, 42 and 44, can be turned on (not depleted) to connect adjacent N wells, 34 and 36, to achieve binning. In the structures shown in FIGS. 1 and 3 the P well regions, 22 in FIG. 1 and 38 and 40 in FIG. 3, can be used as a floating gate sense node for alternative non-destructive readout.

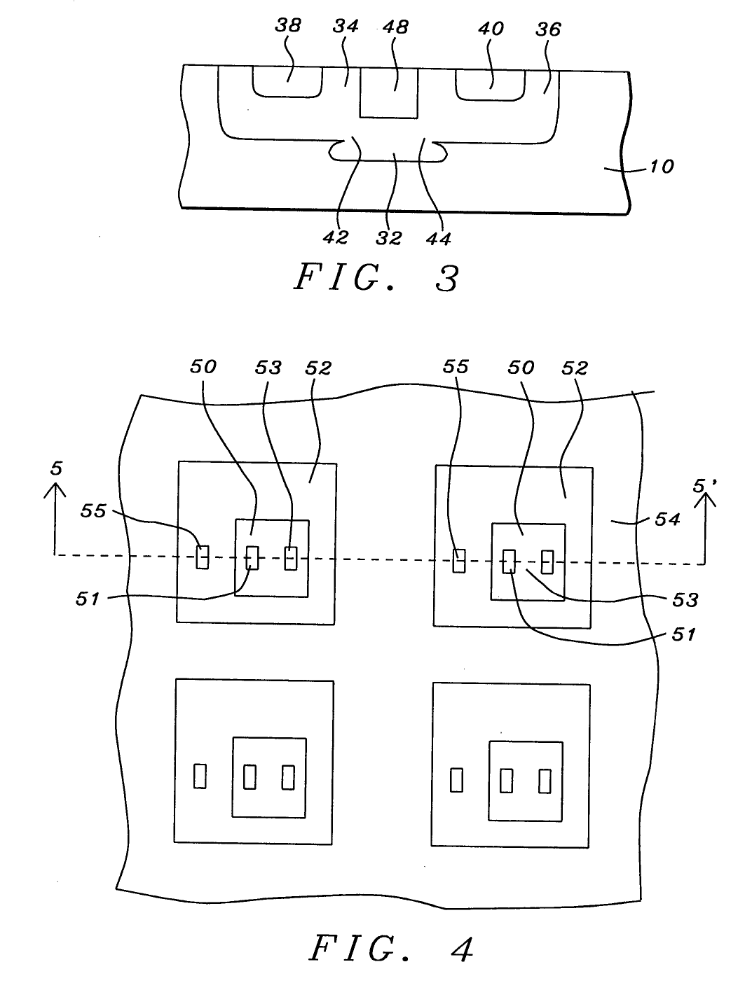

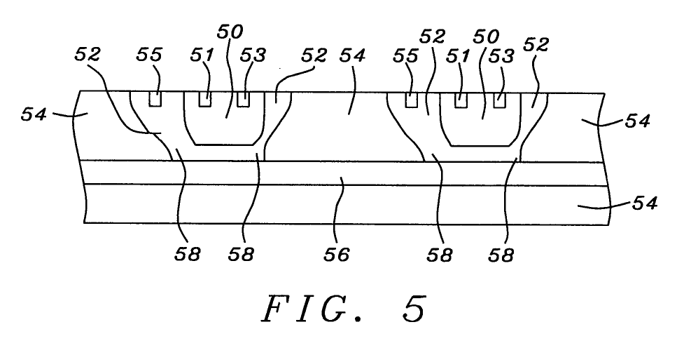

The above description has shown two N wells 34 and 36 which communicate by a single deep N well 32. As indicated above, a structure having a greater number of N wells and a single deep N well can also be used. In this case the N wells communicate to a single deep N well by means of a number of overlap regions. FIG. 4 shows a top view and FIG. 5 shows a cross section view, taken along line 5-5′ of FIG. 4, of an array of N wells 50 formed in a p type substrate 54 with a P well 50 in each of the N wells 52. A deep N well 56 in formed in the substrate 54 extending beneath each of the P wells 50. An overlap region 58 is formed between each of the N wells 52 and the deep N well 56. A first N region 51 and a second N region 53 are formed in each P well 50. A P region 55 is formed in each N well 52. In this case a sufficiently high voltage is applied to deplete all of the overlap regions 58 during the charge integration period. After the charge integration period has been completed, charge transfer can be controlled by controlling the amount of depletion in each of the overlap regions 58. The overlap regions 58 can then be turned on during the reset operation to connect the individual N wells 52 together, thereby achieving reset noise suppression. The overlap regions 58 will then be turned off after reset to isolate the N wells 52 for the next charge accumulation cycle. In this structure the overlap regions 58 are turned on to interconnect the N wells to achieve binning.

The overlap regions 58 are turned on during the reset cycle. The overlap regions 58 are then turned off during the charge integration period. After the completion of the charge integration period the overlap regions 58 can be used to control the charge transfer from the deep N well 56 to each of the N wells 52. The pixel is read by reading the potential of the N wells 56. In one mode of operation the potential of the N wells 56 can be read before and after the transfer of the charge from the deep N well 56 to each N well 56 providing a pixel correlated double sampling operation. The first 51 and second 53 N regions in each of the P wells 50 provide electrical communication to each of the P wells 50. The P region in each of the N wells 52 provide electrical communication to each of the N wells 52. The first N region 51, second N region 53, and P well 50 in each N well 52 can be used as a floating gate field effect transistor. In this structure P well regions 50 formed in each of the N wells 52 can be used as a floating gate sense node for alternative non-destructive readout.

Those skilled in the art will readily recognize that the invention will also work by replacing N wells with P wells, P wells with N wells, N regions with P regions, and P regions with N regions in an n type epitaxial silicon substrate. In this case n regions are replaced by p regions, p regions are replaced by n regions positive potentials are replaced by negative potentials, and negative potentials are replaced by positive potentials.

While the invention has been particularly shown and described with reference to the preferred embodiments thereof, it will be understood by those skilled in the art that various changes in form and details may be made without departing from the spirit and scope of the invention.

What is claimed is:

1. A vertical charge transfer active pixel sensor, comprising:
a p type epitaxial silicon substrate;
an N well formed in said substrate;
a P well formed in said N well;
a deep N well formed in said substrate beneath said P well;
an overlap region formed between said N well and said deep N well wherein the potential of said P well can be set to deplete said overlap region of charge carriers and electrically isolate said N well from said deep N well or can be set so that said overlap region is not depleted of charge and electrically connects said N well to said deep N well;
a first N region and a second N region formed in said P well, wherein said first N region and said second N region provide electrical communication to said P well; and
a P region formed in said N well, wherein said P region provides electrical communication to said N well.

2. The vertical charge transfer active pixel sensor of claim 1 wherein said N well, said deep N well, and said P well have doping levels of less than 1×10¹⁷ impurities per cm³.

3. The vertical charge transfer active pixel sensor of claim 1 wherein said overlap region is not depleted of charge carriers by setting the potential of said P well with respect to said p type epitaxial substrate and the potential of said N well with respect to said p type epitaxial substrate at a first voltage and said overlap region is depleted of charge by setting the potential of said P well with respect to said p type epitaxial substrate at a second voltage while keeping the potential of said N well with respect to said p type epitaxial substrate at said first voltage.

4. The vertical charge transfer active pixel sensor of claim 3 wherein said first voltage is about +3 volts and said second voltage is about −3 volts.

5. The vertical charge transfer active pixel of claim 3 wherein said first voltage and said second voltage are chosen such that the overlap region is depleted of charge during a charge integration period and not depleted of charge after said charge integration period has been completed.

6. The vertical charge transfer active pixel sensor of claim 1 wherein said first N region, said second N region, and said P well can be used to form a floating gate field effect transistor.

7. A vertical charge transfer active pixel sensor, comprising:
an n type epitaxial silicon substrate;
a P well formed in said substrate;
an N well formed in said P well;
a deep P well formed in said substrate beneath said N well;
an overlap region formed between said P well and said deep P well wherein the potential of said N well can be set to deplete said overlap region of charge carriers and electrically isolate said P well from said deep P well or can be set so that said overlap region is not depleted of charge and electrically connects said P well to said deep P well;
a first P region and a second P region formed in said N well, wherein said first P region and said second P region provide electrical communication to said N well; and
an N region formed in said P well, wherein said N region provides electrical communication to said P well.

8. The vertical charge transfer active pixel sensor of claim 7 wherein said P well, said deep P well, and said N well have doping levels of less than 1×10¹⁷ impurities per cm³.

9. The vertical charge transfer active pixel sensor of claim 7 wherein said overlap region is not depleted of charge carriers by setting the potential of said N well with respect to said n type epitaxial substrate and the potential of said P well with respect to said n type epitaxial substrate at a first voltage and said overlap region is depleted of charge by setting the potential of said N well with respect to said n type epitaxial substrate at a second voltage while keeping the potential of said P well with respect to said N type epitaxial substrate at said first voltage.

10. The vertical charge transfer active pixel sensor of claim 9 wherein said first voltage is about −3 volts and said second voltage is about +3 volts.

11. The vertical charge transfer active pixel of claim 9 wherein said first voltage and said second voltage are chosen such that the overlap region is depleted of charge during a charge integration period and not depleted of charge after said charge integration period has been completed.

12. The vertical charge transfer active pixel sensor of claim 7 wherein said first P region, said second P region, and said N well can be used to form a floating gate field effect transistor.

13. A method of operating a vertical charge transfer active pixel sensor, comprising:
providing a p type epitaxial silicon substrate;
providing an N well formed in said substrate;
providing a P well formed in said N well;
providing a deep N well formed in said substrate beneath said P well;
providing an overlap region formed between said N well and said deep N well wherein the potential of said P well can be set to deplete said overlap region of charge carriers and electrically isolate said N well from said deep N well or can be set so that said overlap region is not depleted of charge and electrically connects said N well to said deep N well;
providing a first N region and a second N region formed in said P well, wherein said first N region and said second N region provide electrical communication to said P well;
providing a P region formed in said N well, wherein said P region provides electrical communication to said N well;
resetting said active pixel sensor by setting the potential of said P well and said N well, with respect to said p type epitaxial substrate, to a first voltage;
setting the potential of said P well, with respect to said p type epitaxial substrate, to a second voltage and keeping said N well, with respect to said p type epitaxial substrate, at said first voltage during a charge integration period, wherein said charge integration period is after resetting said active pixel sensor;
disconnecting said N well from any bias voltage, setting the potential of said P well, with respect to said p type epitaxial substrate, to a third voltage after said charge integration period has been completed; and
determining the charge accumulated during the charge integration period.

14. The method of claim 13 wherein said first voltage is +3 volts, said second voltage is −3 volts, and said third voltage is 0 volts.

15. The method of claim 13 wherein said determining the charge accumulated during the charge integration period is accomplished by determining the potential of said N well.

16. The method of claim 13 wherein said N well, said deep N well, and said P well have doping levels of less than 1×10¹⁷ impurities per cm³.

17. The method of claim 13 wherein the doping levels of said N well, said deep N well, and said P well are chosen so that said overlap region is not depleted of charge when the potential of said P well, with respect to said p type epitaxial substrate, is 0 volts and is depleted of charge when the potential of said P well, with respect to said p type epitaxial substrate, is −3 volts.

18. The vertical charge transfer active pixel sensor of claim 13 wherein said first N region, said second N region, and said P well can be used to form a floating gate field effect transistor.
